(19) United States
(12) Patent Application Publication
(10) Pub. No.: US 2024/0222235 A1
(43) Pub. Date: Jul. 4, 2024

(54) SEMICONDUCTOR DEVICE

(71) Applicant: FUJI ELECTRIC CO., LTD., Kawasaki-shi (JP)

(72) Inventor: Ryu ARAKI, Matsumoto-city (JP)

(73) Assignee: FUJI ELECTRIC CO., LTD., Kawasaki-shi (JP)

(21) Appl. No.: 18/496,383

(22) Filed: Oct. 27, 2023

(30) Foreign Application Priority Data
Dec. 28, 2022 (JP) 2022-211522

(51) Int. Cl. H01L 23/495; H01L 23/00; H01L 25/18

(52) U.S. Cl. CPC H01L 23/49562; H01L 24/48; H01L 24/49; H01L 25/18; H01L 2224/48465; H01L 2224/4912; H01L 2924/13055; H01L 2924/13091

(57) ABSTRACT

A wiring member is connected to an output electrode of a semiconductor chip and to a wiring region of a main current lead frame via an insulating spacer. In this case, a snubber capacitor is formed by the wiring member and spacer between the input electrode of a (high-side) semiconductor chip and the output electrode of a (low-side) semiconductor chip. This snubber capacitor absorbs back electromotive force produced due to the wiring inductance of the wiring member and main current lead frame.

### CROSS-REFERENCE TO RELATED APPLICATION

This application is based upon and claims the of priority of the prior Japanese Patent benefit Application No. 2022-211522, filed on Dec. 28, 2022, the entire contents of which are incorporated herein by reference.

### BACKGROUND OF THE INVENTION

### 1. Field of the Invention

The embodiments discussed herein relate to a semiconductor device.

### 2. Background of the Related Art

In a semiconductor device, a free-wheeling diode (FWD) chip and a power transistor chip are bonded to a p-type lead frame, and a FWD chip and a power transistor chip are bonded to an n-type lead frame. In addition, the front-side electrodes of the FWD chip and power transistor chip bonded to the p-type lead frame are connected to the n-type lead frame with a DLB frame (see, for example, Japanese Laid-open Patent Publication No. 2018-081947).

In addition, in a semiconductor power module, the rear-side electrode (collector) of a power transistor is connected to the front surface of a p-side electrode plate, and the rear-side electrode (collector) of a power transistor is connected to the front surface of an output conductive plate. An n-side electrode plate is provided on the rear surface of the output conductive plate via an insulating substrate. The front-side electrode (emitter) of the power transistor connected to the output conductive plate is connected to the n-side electrode plate (see, for example, Japanese Laid-open Patent Publication No. 2009-071130).

### SUMMARY OF THE INVENTION

According to one aspect, there is provided a semiconductor device, including: a first semiconductor chip having a first output electrode on a front surface thereof and a first input electrode on a rear surface thereof; a first lead frame including a first chip region to which the first input electrode of the first semiconductor chip is bonded, and a first wiring region; a second semiconductor chip having a second output electrode on a front surface thereof and a second input electrode on a rear surface thereof, the second semiconductor chip being adjacent to the first chip region; an other lead frame electrically connected to the second output electrode of the second semiconductor chip; and a wiring member connected to the second output electrode of the second semiconductor chip and to the first wiring region of the first lead frame via an insulating member.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view of a semiconductor device according to a first embodiment;

FIGS. 2A and 2B are side views respectively illustrating a long side surface 2a and short side surface 2b of the semiconductor device according to the first embodiment;

FIG. 3 is a plan view of the semiconductor device except for an encapsulating body according to the first embodiment;

FIG. 4 is a plan view of lead frames included in the semiconductor device according to the first embodiment;

FIG. 5 is a side view of the semiconductor device except for the encapsulating body according to the first embodiment;

FIG. 6 is an equivalent circuit diagram illustrating a circuit that implements functions of the semiconductor device according to the first embodiment;

FIG. 7 is a plan view of a semiconductor device except for an encapsulating body according to a reference example;

FIG. 8 is an equivalent circuit diagram illustrating a circuit that implements functions of the semiconductor device according to the reference example;

FIG. 9 is a plan view of a semiconductor device except for an encapsulating body according to a second embodiment;

FIG. 10 is a plan view of a semiconductor device except for an encapsulating body according to a third embodiment;

FIG. 11 is a plan view of lead frames included in the semiconductor device according to the third embodiment;

FIG. 12 is a side view of the semiconductor device except for the encapsulating body according to the third embodiment; and

FIG. 13 is an equivalent circuit diagram illustrating a circuit that implements functions of the semiconductor device according to the third embodiment.

### DETAILED DESCRIPTION OF THE INVENTION

Hereinafter, embodiments will be described with reference to the accompanying drawings. In the following description, the terms “front surface” and “top surface” refer to an X-Y plane facing up (in the +Z direction) in semiconductor devices 1 and 1b of drawings. Similarly, the term “up” refers to an upward direction (the +Z direction) in the semiconductor devices 1 and 1b of the drawings. The terms “rear surface” and “bottom surface” refer to an X-Y plane facing down (in the −Z direction) in the semiconductor devices 1 and 1b of the drawings. Similarly, the term “down” refers to a downward direction (the −Z direction) in the semiconductor devices 1 and 1b of the drawings. The same directionality applies to other drawings, as appropriate. The expression “located above” refers to an upper position (in the +Z direction) in the semiconductor devices 1 and 1b of the drawings. Similarly, the expression “located below” refers to a lower position (in the −Z direction) in the semiconductor devices 1 and 1b of the drawings. The terms “front surface,” “top surface,” “up,” “rear surface,” “bottom surface,” “down, ” and “side surface” are used for convenience to describe relative positional relationships, and do not limit the technical ideas of the embodiments. For example, the terms “up” and “down” are not always related to the vertical directions to the ground. That is, the “up” and “down” directions are not limited to the gravity direction. In addition, in the following description, the term “main component” refers to a component contained at a volume ratio of 80 vol % or more. The expression “being approximately equal” may allow an error range of ±10%. In addition, the expressions “being perpendicular” and “being parallel” may allow an error range of ±10%.

### First Embodiment

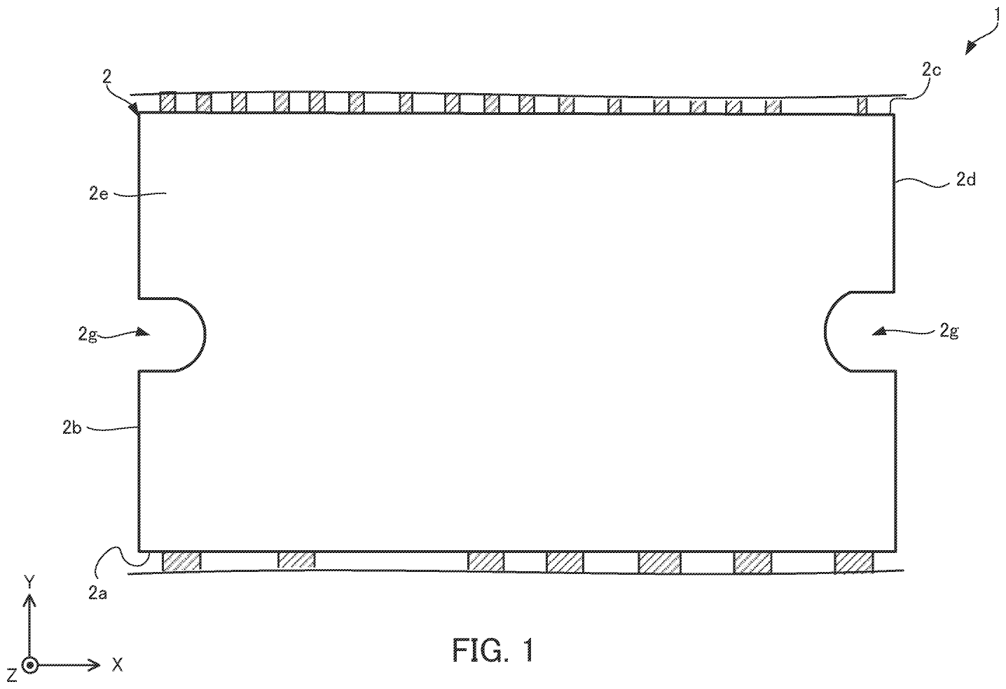

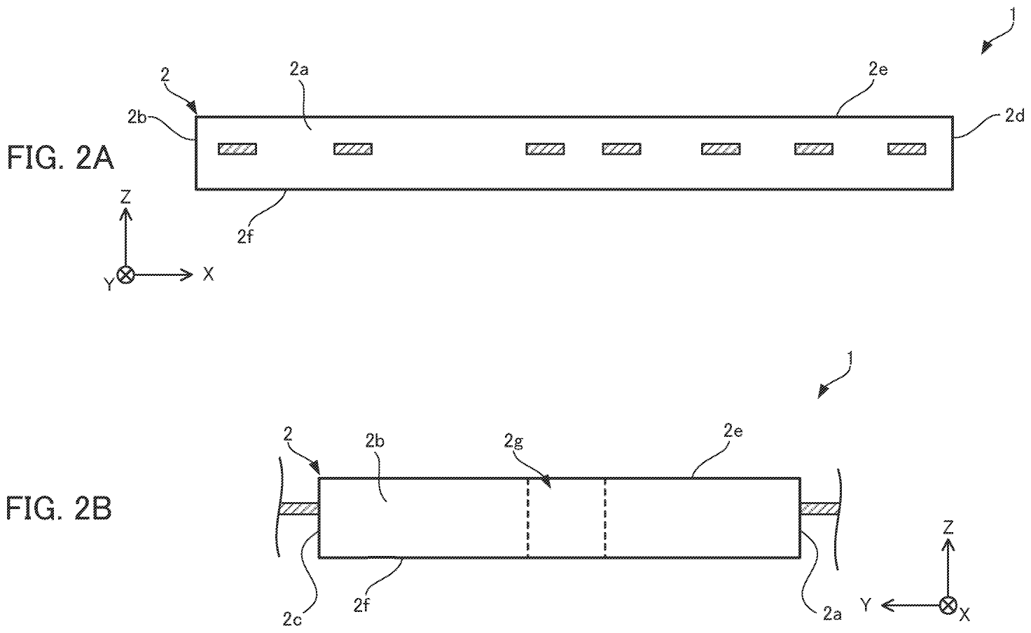

First, the appearance of a semiconductor device 1 according to a first embodiment will be described with reference to FIGS. 1, 2A, and 2B. FIG. 1 is a plan view of the semiconductor device according to the first embodiment, and FIGS. 2A and 2B are side views respectively illustrating a long side surface 2a and short side surface 2b of the semiconductor device according to the first embodiment. In this connection, FIG. 2A is a side view of the semiconductor device 1 of FIG. 1 seen in the +Y direction. FIG. 2B is a side view of the semiconductor device 1 of FIG. 1 seen in the +X direction.

The semiconductor device 1 includes semiconductor chips and various lead frames, which will be described later, and an encapsulating body 2 sealing these. The encapsulating body 2 has a flat plate shape and forms a cube. The encapsulating body 2 has a top surface 2e that is rectangular in plan view, and a bottom surface 2f opposite to the top surface 2e. The top surface 2e and bottom surface 2f are approximately the same in shape and size. The top surface 2e and bottom surface 2f are approximately parallel to each other. In addition, in plan view, the encapsulating body 2 has a long side surface 2a, short side surface 2b, long side surface 2c, and short side surface 2d that surround the four sides of each of the top surface 2e and bottom surface 2f in order. The long side surfaces 2a and 2c correspond to the long side of the semiconductor device 1 in plan view, and the short side surfaces 2b and 2d correspond to the short side of the semiconductor device 1 in plan view. That is, the long side surfaces 2a and 2c are parallel to the long-side direction of the semiconductor device 1, and the short side surfaces 2b and 2d are parallel to the short-side direction of the semiconductor device 1.

In addition, in the semiconductor device 1, fastening portions 2g are formed in the pair of short side surfaces 2b and 2d of the encapsulating body 2. For example, the fastening portions 2g may be formed to pass through approximately the centers of the short side surfaces 2b and 2d, respectively. The positions of the fastening portions 2g illustrated in FIG. 1 are just an example and are not limited thereto. The fastening portions 2g each have such a diameter as to allow the insertion of a bolt (not illustrated). The fastening portions 2g penetrate between the top surface 2e and bottom surface 2f of the encapsulating body 2. Referring to FIGS. 1, 2A, and 2B, the fastening portions 2g each form a U-shape in plan view. The shapes of the fastening portions 2g are not limited thereto, but may be circular in plan view. A cooling unit may be fastened to the rear surface (bottom surface 2f) of the semiconductor device 1 by inserting bolts into the fastening portions 2g. By doing so, the cooling unit is attached to the semiconductor device 1. Examples of the cooling unit include a heatsink and a cooling device using a coolant.

In addition, various lead frames extend from the pair of long side surfaces 2a and 2c of the encapsulating body 2. To put it simply, main current lead frames extend from the long side surface 2a, and control lead frames extend from the long side surface 2c. These lead frames will be described in detail later.

This encapsulating body 2 contains a thermosetting resin and an inorganic filler, which is contained in the thermosetting resin. For example, the thermosetting resin contains, as a main component, at least one selected from the group including an epoxy resin, a phenolic resin, and a melamine resin. The thermosetting resin preferably contains an epoxy resin as a main component. In addition, as the inorganic filler, an inorganic material with high insulation and high thermal conductivity is used. For example, the inorganic material contains at least one selected from the group including aluminum oxide, aluminum nitride, silicon oxide, silicon nitride, and boron nitride, as a main component. The inorganic filler preferably contains silicon oxide as a main component. For example, the inorganic filler accounts for 70 vol % to 90 vol %, inclusive, of the total raw material of the encapsulating body 2.

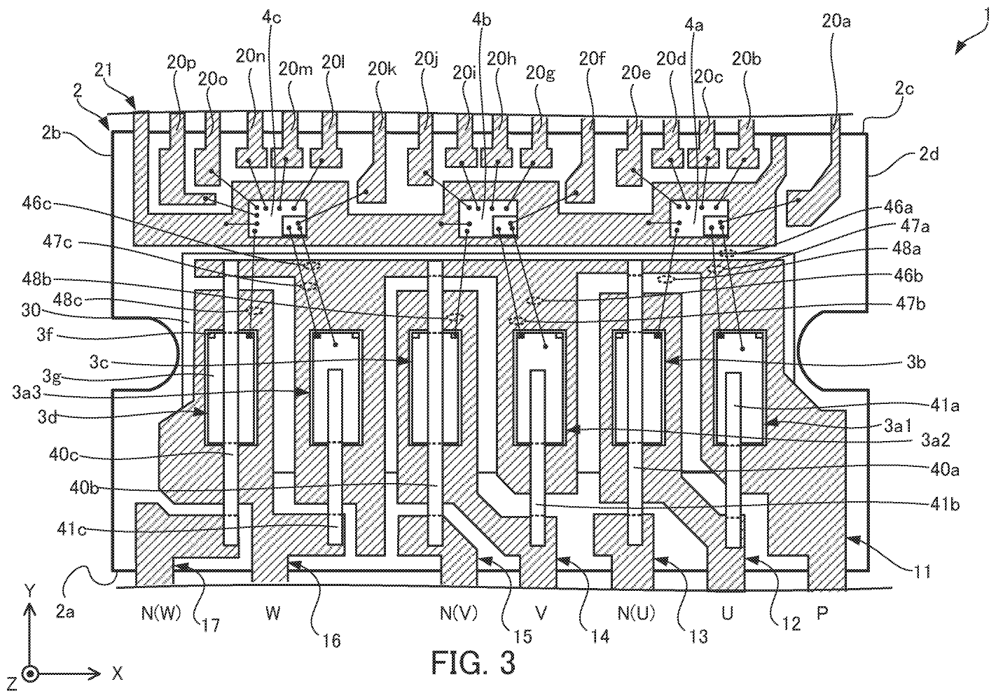

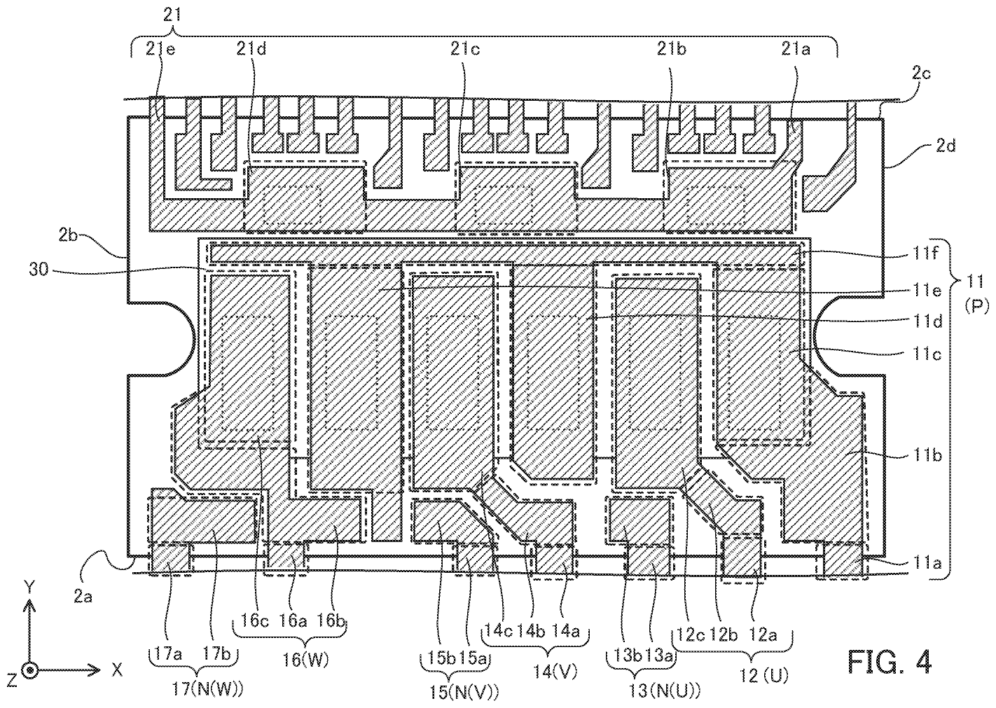

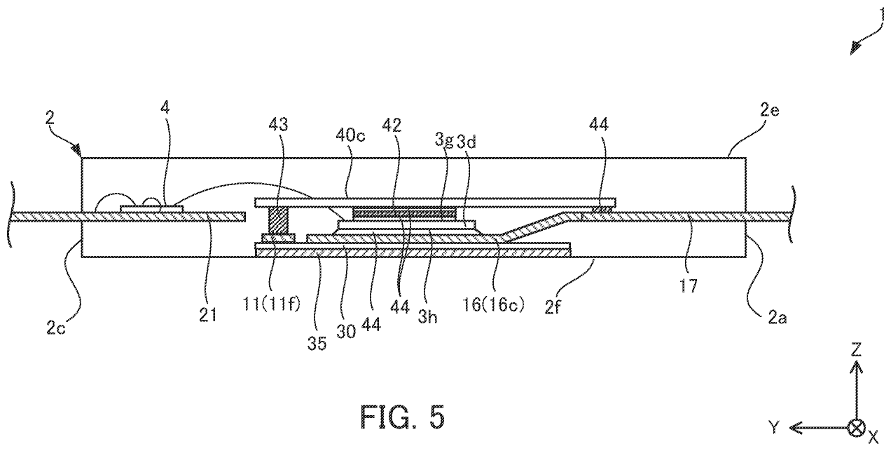

The following describes the components including semiconductor chips and various lead frames that are sealed with the encapsulating body 2 included in the semiconductor device 1, with reference to FIGS. 3 to 5. FIG. 3 is a plan view of the semiconductor device except for the encapsulating body according to the first embodiment. FIG. 4 is a plan view of lead frames included in the semiconductor device according to the first embodiment. FIG. 5 is a side view of the semiconductor device except for the encapsulating body according to the first embodiment. In this connection, FIG. 3 is a plan view of the semiconductor device 1 of FIG. 1 except for the encapsulating body 2. FIG. 4 illustrates only various lead frames that are sealed with the encapsulating body 2 in FIG. 3. FIG. 5 is a side view of a −X-side end portion (at the side where the short side surface 2b is located) seen in FIG. 3. That is, FIG. 5 is a side view seen in the +X direction in FIG. 3. In addition, FIGS. 3 to 5 illustrate the outline of the encapsulating body 2, just for reference.

The semiconductor device 1 includes main current lead frame (first lead frame) 11, main current lead frames (second lead frames) 12, 14, 16, and main current lead frames (third lead frames) 13, 15, 17, control lead frames 20a to 20p and 21, an insulating sheet 30, a heat dissipation plate 35, semiconductor chips (first semiconductor chips) 3a1 to 3a3 and semiconductor chips (second semiconductor chips) 3b to 3d, and control integrated circuits (ICs) 4a to 4c. In addition, the semiconductor device 1 includes wiring members 40a to 40c and 41a to 41c. The control ICs 4a to 4c are electrically and mechanically connected to the semiconductor chips 3a1 to 3a3 and 3b to 3d with control wires 47a to 47c and 48a to 48c and sense wires 46a to 46c.

The control wires 47a to 47c and 48a to 48c and sense wires 46a to 46c are made of a metal with high electrical conductivity as a main component. Examples of the metal here include gold, silver, copper, aluminum, and an alloy containing at least one of these.

The main current lead frames 11 to 17 extend outward (in the −Y direction (second direction)) from the long side surface 2a of the encapsulating body 2. The control lead frames 20a to 20p and 21 extend outward (in the +Y direction (second direction)) from the long side surface 2c of the encapsulating body 2. The portions of these lead frames extending from the long side surfaces 2a and 2c are not illustrated in the drawings.

The main current lead frames 11 to 17 are made of a material with high electrical conductivity. Examples of the material include copper, aluminum, and an alloy containing at least one of these. Here, the main current lead frames 11 to 17 are made of copper or a copper alloy as a main component. In addition, the main current lead frames 11 to 17 may be plated with a material with high corrosion resistance. Examples of the plating material used here include nickel, gold, and an alloy containing at least one of these. The main current lead frames 11 to 17 are spaced by a gap of a predetermined distance or more from one another. This keeps the creepage distances between the main current lead frames 11 to 17.

The main current lead frame 11 integrally includes an external bonding region 11a, a wiring region 11b, chip regions 11c, 11d, and 11e, and a wiring region 11f, as illustrated in FIG. 4. In this connection, dotted rectangles depicted in the chip regions 11c, 11d, and 11e indicate the positions of the semiconductor chips 3a1, 3a2, and 3a3, respectively. The semiconductor chips 3a1, 3a2, and 3a3 are bonded respectively to the chip regions 11c, 11d, and 11e via a bonding member 44. The bonding member 44 is a solder or a sintered material. The solder is a lead-free solder containing a predetermined alloy as a main component. For example, the predetermined alloy is at least one of a tin-silver alloy, a tin-zinc alloy, and a tin-antimony alloy. The solder may contain an additive such as copper, bismuth, indium, nickel, germanium, cobalt, or silicon. In addition, the sintered material is a powder of silver, gold, or copper, for example.

The external bonding region 11a extends in the −Y direction from a portion of the long side surface 2a of the encapsulating body 2 adjacent to the short side surface 2d in plan view. The external bonding region 11a may be bent at any point so as to extend in the +Z direction.

The wiring region 11b integrally connects to the external bonding region 11a and the chip region 11c. The wiring region 11b extends from the external bonding region 11a to the chip region 11c in the direction toward the long side surface 2c in parallel to the short side surface 2d.

The chip regions 11c to 11e are arranged with predetermined equal gaps therebetween in a line passing through the centers of the short side surfaces 2b and 2d in parallel to the long side surfaces 2a and 2c in plan view. The wiring region 11f is located closer to the long side surface 2c than are the main current lead frames 12 to 16, which will be described later, and extends in the direction from the short side surface 2d toward the short side surface 2b in parallel to the long side surfaces 2a and 2c. The chip region 11e includes a region projecting between wiring regions 15b and 16b of the main current lead frames 15 and 16 to be described later. This projecting region contributes to an improvement in the heat dissipation property of the chip region 11e.

The wiring region 11f is integrally connected to the sides of the chip regions 11c to 11e closest to the long side surface 2c. In this connection, the wiring region 11f may extend beyond the chip region 11e toward the short side surface 2b up to a chip region 16c to be described later. More specifically, the wiring region 11f may extend up to a position that is closer to the short side surface 2b than is the semiconductor chip 3d disposed in the chip region 16c.

The main current lead frame 12 integrally includes an external bonding region 12a, a wiring region 12b, and a chip region 12c, as illustrated in FIG. 4. In this connection, a dotted rectangle depicted in the chip region 12c indicates the position of the semiconductor chip 3b. The semiconductor chip 3b is bonded to the chip region 12c via the bonding member 44.

In plan view, the external bonding region 12a is located next to and on the −X side of the external bonding region 11a and extends from the long side surface 2a of the encapsulating body 2 in the −Y direction. The external bonding region 12a may be bent at any point so as to extend in the +Z direction.

The wiring region 12b integrally connects to the external bonding region 12a and the chip region 12c. The wiring region 12b extends from the external bonding region 12a to the chip region 12c in a direction diagonal to the −X and +Y directions. The chip region 12c is located between the chip regions 11c and 11d with equal gaps from the chip regions 11c and 11d and wiring region 11f.

The main current lead frame 13 integrally includes an external bonding region 13a and a wiring region 13b, as illustrated in FIG. 4. In plan view, the external bonding region 13a is located next to and on the −X side of the external bonding region 12a and extends outward (in the −Y direction) from the long side surface 2a of the encapsulating body 2. The external bonding region 13a may be bent at any point so as to extend in the +Z direction.

The wiring region 13b is integrally connected to the external bonding region 13a. The wiring region 13b extends from the external bonding region 13a up to just before the chip region 12c in the direction toward the long side surface 2c in parallel to the short side surfaces 2b and 2d.

The main current lead frame 14 integrally includes an external bonding region 14a, a wiring region 14b, and a chip region 14c, as illustrated in FIG. 4. In this connection, a dotted rectangle depicted in the chip region 14c indicates the position of the semiconductor chip 3c. The semiconductor chip 3c is bonded to the chip region 14c via the bonding member 44.

In plan view, the external bonding region 14a is located next to and on the −X side of the external bonding region 13a and extends from the long side surface 2a of the encapsulating body 2 in the −Y direction. The external bonding region 14a may be bent at any point so as to extend in the +Z direction.

The wiring region 14b integrally connects to the external bonding region 14a and the chip region 14c. The wiring region 14b extends from the external bonding region 14a to the chip region 14c in a direction diagonal to the −X and +Y directions. The chip region 14c is located between the chip regions 11d and 11e with predetermined gaps from the chip regions 11d and 11e and wiring region 11f.

The main current lead frame 15 integrally includes an external bonding region 15a and the wiring region 15b, as illustrated in FIG. 4. In plan view, the external bonding region 15a is located next to and on the −X side of the external bonding region 14a and extends outward (in the −Y direction) from the long side surface 2a of the encapsulating body 2. The external bonding region 15a may be bent at any point so as to extend in the +Z direction. The wiring region 15b is integrally connected to the external bonding region 15a. The wiring region 15b extends from the external bonding region 15a up to just before the chip region 14c in the direction toward the long side surface 2c.

The main current lead frame 16 integrally includes an external bonding region 16a, the wiring region 16b, and the chip region 16c, as illustrated in FIG. 4. In this connection, a dotted rectangle depicted in the chip region 16c indicates the position of the semiconductor chip 3d. The semiconductor chip 3d is bonded to the chip region 16c via the bonding member 44.

In plan view, the external bonding region 16a is located next to and on the −X side of the external bonding region 15a and extends from the long side surface 2a of the encapsulating body 2 in the −Y direction. The external bonding region 16a may be bent at any point so as to extend in the +Z direction.

The wiring region 16b integrally connects to the external bonding region 16a and the chip region 16c. The wiring region 16b extends from the external bonding region 16a to the chip region 16c in the direction toward the long side surface 2c. The chip region 16c is located next to and on the −X side of the chip region 11e with predetermined gaps from the chip region 11e and wiring region 11f.

The main current lead frame 17 integrally includes an external bonding region 17a and a wiring region 17b, as illustrated in FIG. 4. In plan view, the external bonding region 17a is located next to and on the −X side of the external bonding region 16a and extends outward (in the −Y direction) from the long side surface 2a of the encapsulating body 2. The external bonding region 17a may be bent at any point so as to extend in the +Z direction. The wiring region 17b is integrally connected to the external bonding region 17a. The wiring region 17b extends from the external bonding region 17a up to just before the wiring region 16b.

In this connection, the external bonding regions 11a, 12a, 14a, and 16a of the main current lead frames 11, 12, 14, and 16 and the main current lead frames 13, 15, and 17 are located vertically above (in the +Z direction) the chip regions 11c to 11e, 12c, 14c, and 16c and wiring region 11f. The wiring regions 11b, 12b, 14b, and 16b are inclined to connect the external bonding regions 11a, 12a, 14a, and 16a to the chip regions 11c, 12c, 14c, and 16c, respectively.

The insulating sheet 30 is rectangular in plan view. The insulating sheet 30 contains a thermosetting rein and an inorganic filler. For example, the thermosetting resin contains, as a main component, at least one selected from the group including an epoxy resin, phenolic resin, melamine resin, and polyimide resin, and preferably contains an epoxy resin as a main component. The inorganic filler contains an inorganic containing, as a main component, at least one selected from the group including aluminum oxide, aluminum nitride, silicon oxide, silicon nitride, and boron nitride. On this insulating sheet 30, at least the chip regions 11c to 11e and wiring region 11f of the main current lead frame 11 and the chip regions 12c, 14c, and 16c of the main current lead frames 12, 14, and 16 are located.

The heat dissipation plate 35 is rectangular in plan view, and is the same or greater in size than the insulating sheet 30. This heat dissipation plate 35 is made of a metal with high thermal conductivity as a main component. Examples of the metal include copper, aluminum, and an alloy containing one of these. Plating may be performed on the heat dissipation plate 35 to improve its corrosion resistance. Examples of the plating material used here include nickel, a nickel-phosphorus alloy, and a nickel-boron alloy. The rear surface of the heat dissipation plate 35 is exposed from the bottom surface 2f of the encapsulating body 2. In this case, the rear surface of the heat dissipation plate 35 is flush with the bottom surface 2f of the encapsulating body 2. Alternatively, the rear surface of the heat dissipation plate 35 may project from the bottom surface 2f in the −Z direction. In the present embodiment, the case where the rear surface of the heat dissipation plate 35 is flush with the bottom surface 2f of the encapsulating body 2 is exemplified (FIG. 5).

The semiconductor chips 3a1 to 3a3 and 3b to 3d are reverse conducting-insulated gate bipolar transistor (RC-IGBT) switching elements, for example. An RC-IGBT has an IGBT and FWD fabricated on a single chip. In the RC-IGBT chip, the IGBT and FWD are connected in inverse parallel. For example, these semiconductor chips 3a1 to 3a3 and 3b to 3d may be formed of silicon.

The semiconductor chips 3a1 to 3a3 and 3b to 3d of this type each have a gate electrode serving as a control electrode 3f and an emitter electrode serving as an output electrode 3g on the front surface thereof. In this connection, the semiconductor chips 3a1 to 3a3 and 3b to 3d each have control electrodes 3f at corners thereof (in FIG. 3, two corners located on the side where the long side surface 2c is located). The output electrode 3g is provided on the front surface except for the area of the control electrode 3f. In addition, the semiconductor chips 3a1 to 3a3 and 3b to 3d each have a collector electrode serving as an input electrode 3h on the rear surface thereof. Furthermore, the semiconductor chips 3a1 to 3a3 and 3b to 3d illustrated in FIG. 3 are arranged such that their control electrodes 3f face toward the long side surface 2c.

Alternatively, the semiconductor chips 3a1 to 3a3 and 3b to 3d may be power devices made of silicon carbide. One example of the power devices is a power metal-oxide-semiconductor field-effect transistor (MOSFET). The body diode of a power MOSFET may perform the same function as the FWD of an RC-IGBT. The semiconductor chips 3a1 to 3a3 and 3b to 3d of this type each have a gate electrode serving as the control electrode 3f and a source electrode serving as the output electrode 3g on the front surface thereof, and a drain electrode serving as the input electrode 3h on the rear surface thereof.

The control lead frames 20a to 20p and 21 are made of a material with high electrical conductivity. Examples of the material here include copper, aluminum, and an alloy containing at least one of these. In this embodiment, the control lead frames 20a to 20p and 21 are made of copper or a copper alloy as a main component. In addition, the control lead frames 20a to 20p and 21 may be plated with a material with high corrosion resistance. Examples of the plating material used here include nickel, gold, and an alloy containing at least one of these. In addition, the control lead frames 20a to 20p and 21 are spaced by a gap of a predetermined distance or more from one another. This keeps the creepage distances between the control lead frames 20a to 20p and 21.

The control lead frames 20a to 20p are provided on the side of the wiring region 11f of the main current lead frame 11 where the long side surface 2c is located. In addition, the control lead frames 20a to 20p are arranged in the direction from the short side surface 2d toward the short side surface 2b along the long side surface 2c. The control lead frames 20a to 20p extend outward (in the +Y direction) from the long side surface 2c of the encapsulating body 2 in plan view. Each control lead frame 20a to 20p may be bent at any point so as to extend in the +Z direction.

The control lead frame 21 has a U-shape in plan view and includes IC regions 21b to 21d and external bonding regions 21a and 21e. The external bonding region 21a is provided in the vicinity of the corner formed by the long side surface 2c and short side surface 2d between the control lead frames 20a and 20b, as illustrated in FIG. 4. In plan view, the external bonding region 21a extends outward (in the +Y direction) from the long side surface 2c of the encapsulating body 2, as illustrated in FIG. 4. The external bonding region 21a may be bent at any point so as to extend in the +Z direction.

The external bonding region 21e is provided next to and on the −X side of the control lead frame 20p in the vicinity of the corner formed by the long side surface 2c and short side surface 2b, as illustrated in FIG. 4. The external bonding region 21e extends outward (in the +Y direction) from the long side surface 2c of the encapsulating body 2 in plan view. The external bonding region 21e may be bent at any point so as to extend in the +Z direction.

This control lead frame 21 starts with the external bonding region 21a extending inward toward the long side surface 2a, extends along the wiring region 11f on a side of the wiring region 11f of the main current lead frame 11, and ends with the external bonding region 21e. The portion of the control lead frame 21 extending along the wiring region 11f of the main current lead frame 11 has the IC regions 21b to 21d. Control ICs 4a to 4c are disposed in the IC regions 21b to 21d, respectively, each via the bonding member 44 (not illustrated).

The control ICs 4a to 4c are examples of control chips, and are each a hybrid IC that serves as both a high voltage integrated circuit (HVIC) and a low voltage integrated circuit (LVIC) in order to control both the high-side semiconductor chips 3a1 to 3a3 and the low-side semiconductor chips 3b to 3d. The control ICs 4a to 4c are connected respectively to the control lead frames 20a to 20e, 20f to 20j, and 20k to 20p with wires (reference numerals omitted). In addition, the control ICs 4a to 4c are connected to the control lead frame 21 with wires (reference numerals omitted).

The control ICs 4a to 4c are each connected directly to at least one control electrode 3f of the corresponding one of the high-side semiconductor chips 3a1 to 3a3 with the corresponding one of the control wires 47a to 47c. Furthermore, the control ICs 4a to 4c are connected directly to the output electrodes 3g of the high-side semiconductor chips 3a1 to 3a3 with the sense wires 46a to 46c, respectively. In addition, the control ICs 4a to 4c are each connected directly to at least one control electrode 3f of the corresponding one of the low-side semiconductor chips 3b to 3d with the corresponding one of the control wires 48a to 48c.

The wiring members 40a to 40c and 41a to 41c are made of a material with high electrical conductivity. Examples of the material used here include copper, aluminum, and an alloy containing at least one of these. In this embodiment, the wiring members 40a to 40c and 41a to 41c are made of copper or a copper alloy as a main component. The wiring members 40a to 40c and 41a to 41c may be plated with a material with high corrosion resistance. Examples of the plating material used here include nickel, gold, and an alloy containing at least one of these. In addition, the wiring members 40a to 40c and 41a to 41c each have a linear stripe shape in plan view. The wiring members 40a to 40c and 41a to 41c are provided in parallel to the short side surfaces 2b and 2d and in perpendicular to the long side surfaces 2a and 2c. For example, the widths in the ±X directions (first direction) of the wiring members 40a to 40c and 41a to 41c are in the range of 0.5 mm to 3.5 mm, inclusive, and the thicknesses in the ±Z directions thereof are in the range of 0.1 mm to 3.0 mm, inclusive.

The wiring members 40a to 40c are electrically bonded at the middle portions thereof to the output electrodes 3g of the semiconductor chips 3b to 3d bonded to the main current lead frames 12, 14, and 16, respectively, each via the bonding member 44, a spacer 42, and the bonding member 44. In this connection, FIG. 5 illustrates the wiring member 40c bonded to the semiconductor chip 3d as an example. The other wiring members 40a and 40b are bonded to the semiconductor chips 3b and 3c, respectively, in the same manner.

The spacer 42 is made of a material with high electrical conductivity. Examples of the material used here include copper, aluminum, and an alloy containing at least one of these. In this embodiment, the spacer 42 contains copper or a copper alloy as a main component. In this connection, the wiring members 40a to 40c each may have a projecting portion at a position facing the output electrode 3g of the corresponding one of the semiconductor chips 3b to 3d, so as to be bonded at the projecting portion to the output electrode 3g.

In addition, the −Y-side end portions of the wiring members 40a to 40c closest to the long side surface 2a are electrically connected to the wiring regions 13b, 15b, and 17b of the main current lead frames 13, 15, and 17, respectively, each via the bonding member 44.

In addition, the +Y-side end portions of the wiring members 40a to 40c closest to the long side surface 2c are connected to the wiring region 11f of the main current lead frame 11, each via a spacer 43.

The spacers 43 are made of an insulating material with dielectric properties. The material of the spacers 43 contains plastic or ceramics as a main component, for example. In place of the spacers 43 made of such an insulating material, the +Y-side end portions of the wiring members 40a to 40c each may be connected to the wiring region 11f of the main current lead frame 11 via a chip capacitor.

The +Y-side end portions of the wiring members 41a to 41c closest to the long side surface 2c are electrically bonded to the output electrodes 3g of the semiconductor chips 3a1, 3a2, and 3a3 bonded to the main current lead frame 11, respectively, each via the bonding member 44 and the above-described spacer 42. In addition, the −Y-side end portions of the wiring members 41a to 41c closest to the long side surface 2a are electrically connected to the wiring regions 12b, 14b, and 16b of the main current lead frames 12, 14, and 16, respectively, each via the bonding member 44. In this connection, in place of the bonding members 44, the wiring members 41a to 41c may be connected only using a conductive adhesive. In addition, the +Y-side end portions of the wiring members 41a to 41c each may have a projecting portion.

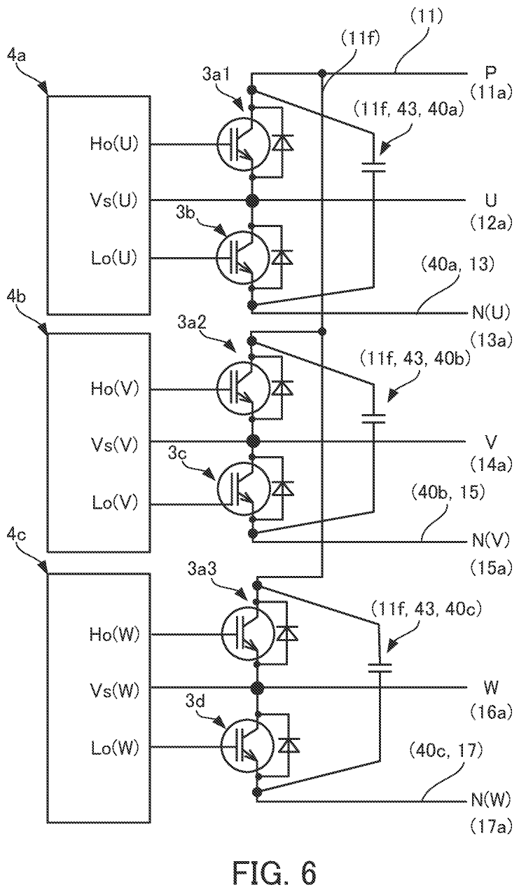

The following describes a circuit configuration that is implemented by the above-described main current lead frames 11 to 17, control lead frames 20a to 20p and 21, wiring members 40a to 40c and 41a to 41c, semiconductor chips 3a1 to 3a3 and 3b to 3d, and control ICs 4a to 4c with reference to FIG. 6, as well as FIGS. 3 to 5. FIG. 6 is an equivalent circuit diagram illustrating a circuit that implements functions of the semiconductor device according to the first embodiment.

The semiconductor device 1 includes a three-phase inverter circuit, as illustrated in FIG. 6. The inverter circuit is to convert direct current to alternating current. The positive electrode and negative electrode of an external direct current power supply are connected to a high-potential connecting point P and low-potential connecting points N(U), N(V), and N (W). In addition, a load is connected to connecting points U, V, and W. The semiconductor chips 3a1 to 3a3 and 3b to 3d convert direct current coming from the connecting point P according to control signals received from the control ICs 4a to 4c and output three-phase alternating current from the connecting points U, V, and W.

The connecting point P corresponds to the external bonding region 11a of the main current lead frame 11. The main current lead frame 11 is connected to the input electrode 3h of the semiconductor chip 3a1. The output electrode 3g of the semiconductor chip 3a1 on the main current lead frame 11 is connected to the input electrode 3h of the semiconductor chip 3b via the wiring member 41a and main current lead frame 12.

The connecting point U corresponds to the external bonding region 12a of the main current lead frame 12, and the input electrode 3h of the semiconductor chip 3b is connected to the main current lead frame 12. The connecting point N (U) corresponds to the external bonding region 13a of the main current lead frame 13 and is connected to the output electrode 3g of the semiconductor chip 3b via the wiring member 40a.

In addition, a snubber capacitor is formed by the wiring region 11f, spacer 43 (and bonding member 44), and wiring member 40a between the input electrode 3h of the semiconductor chip 3a1 and the output electrode 3g of the semiconductor chip 3b.

Note that the control IC 4a is connected to the control lead frames 20a to 20e and 21 with wires. The control IC 4a inputs a control signal to the control electrode 3f of the high-side semiconductor chip 3a1 and to the control electrode 3f of the low-side semiconductor chip 3b, according to signals received from the control lead frames 20a to 20e and 21.

The connecting point P corresponds to the external bonding region 11a of the main current lead frame 11, and the main current lead frame 11 is connected to the input electrode 3h of the semiconductor chip 3a2. The output electrode 3g of the semiconductor chip 3a2 on the main current lead frame 11 is connected to the input electrode 3h of the semiconductor chip 3c via the wiring member 41b and main current lead frame 14.

The connecting point V corresponds to the external bonding region 14a of the main current lead frame 14, and the input electrode 3h of the semiconductor chip 3c is connected to the main current lead frame 14. The input electrode 3h of the semiconductor chip 3c and the output electrode 3g of the semiconductor chip 3a2 are connected to each other via the main current lead frame 14 and wiring member 41b. The connecting point N (V) corresponds to the external bonding region 15a of the main current lead frame 15 and is connected to the output electrode 3g of the semiconductor chip 3c via the wiring member 40b.

In addition, a snubber capacitor is formed by the wiring region 11f, spacer 43 (and bonding member 44), and wiring member 40b between the input electrode 3h of the semiconductor chip 3a2 and the output electrode 3g of the semiconductor chip 3c.

Note that the control IC 4b is connected to the control lead frames 20f to 20j and 21 with wires. The control IC 4b inputs a control signal to the control electrode 3f of the high-side semiconductor chip 3a2 and to the control electrode 3f of the low-side semiconductor chip 3c, according to signals received from the control lead frames 20f to 20j and 21.

The connecting point P corresponds to the external bonding region 11a of the main current lead frame 11, and the main current lead frame 11 is connected to the input electrode 3h of the semiconductor chip 3a3. The output electrode 3g of the semiconductor chip 3a3 on the main current lead frame 11 is connected to the input electrode 3h of the semiconductor chip 3d via the wiring member 41c and main current lead frame 16.

The connecting point W corresponds to the external bonding region 16a of the main current lead frame 16, and the input electrode 3h of the semiconductor chip 3d is connected to the main current lead frame 16. The connecting point N (W) corresponds to the external bonding region 17a of the main current lead frame 17 and is connected to the output electrode 3g of the semiconductor chip 3d via the wiring member 40c.

In addition, a snubber capacitor is formed by the wiring region 11f, spacer 43 (and bonding member 44), and wiring member 40c between the input electrode 3h of the semiconductor chip 3a3 and the output electrode 3g of the semiconductor chip 3d.

Note that the control IC 4c is connected to the control lead frames 20k to 20p and 21 with wires. The control IC 4c inputs a control signal to the control electrode 3f of the high-side semiconductor chip 3a3 and to the control electrode 3f of the low-side semiconductor chip 3d, according to signals received from the control lead frames 20k to 20p and 21.

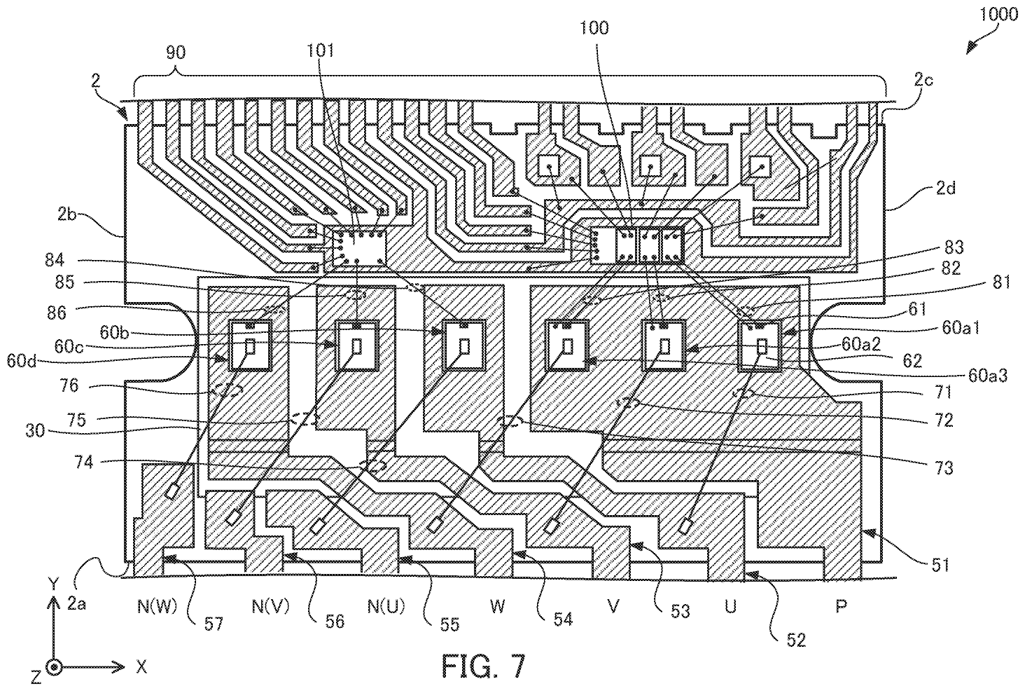

The following describes a semiconductor device according to a reference example, with reference to FIG. 7. FIG. 7 is a plan view of the semiconductor device except for an encapsulating body according to the reference example. In this connection, FIG. 7 is a plan view of a semiconductor device 1000 except for an encapsulating body 2, and corresponds to FIG. 3 illustrating the semiconductor device 1. FIG. 7 illustrates the outline of the encapsulating body 2 as well.

The semiconductor device 1000 includes main current lead frames 51 to 57, a plurality of control lead frames 90, an insulating sheet 30, a heat dissipation plate (not illustrated), semiconductor chips 60a1 to 60a3 and 60b to 60d, and control ICs 100 and 101. In addition, the semiconductor device 1000 includes main current wires 71 to 76. Furthermore, the control ICs 100 and 101 are electrically and mechanically connected to the semiconductor chips 60a1 to 60a3 and 60b to 60d with control wires 81 to 86. The above components of the semiconductor device 1000 are sealed with the encapsulating body 2. FIG. 7 illustrates the bonding portions of the main current wires 71 to 76 in white rectangles.

The main current lead frames 51 to 57 extend outward (in the −Y direction) from a long side surface 2a of the encapsulating body 2. The control lead frames 90 extend outward (in the +Y direction) from a long side surface 2c of the encapsulating body 2. In FIG. 7, the portions of the main current lead frames 51 to 57 extending from the long side surface 2a and the portions of the plurality of control lead frames 90 extending from the long side surface 2c are not illustrated. In addition, the main current lead frames 51 to 57 and the plurality of control lead frames 90 may be made of the same materials as and have the same thicknesses as the main current lead frames 11 to 17 and control lead frames 20a to 20p and 21 included in the semiconductor device 1, respectively. In addition, the insulating sheet 30 and heat dissipation plate 35 are the same as those included in the semiconductor device 1.

The main current lead frames 51 to 54 are arranged in order in the direction from a short side surface 2d toward a short side surface 2b, as illustrated in FIG. 7. The main current lead frames 55 to 57 are arranged in order in the −X direction along the long side surface 2a. In addition, regions of the main current lead frames 51 to 54 where the semiconductor chips 60a1 to 60a3 and 60b to 60d are disposed are located on the insulating sheet 30. In this connection, the semiconductor chips 60a1 to 60a3 and 60b to 60d each have a control electrode 61 and an output electrode 62 on the front surface thereof and an input electrode (not illustrated) on the rear surface thereof.

On the main current lead frame 51, the high-side semiconductor chips 60a1 to 60a3 are arranged in order in the direction from the short side surface 2d toward the short side surface 2b. In this case, the semiconductor chips 60a1 to 60a3 are arranged in a line parallel to the long side surface 2a in plan view. The low-side semiconductor chips 60b to 60d are bonded to the main current lead frames 52 to 54, respectively.

The input electrodes on the rear surfaces of the semiconductor chips 60a1 to 60a3 are bonded to the main current lead frame 51. The output electrodes 62 of the semiconductor chips 60a1 to 60a3 on the main current lead frame 51 are connected directly to the main current lead frames 52 to 54 via the main current wires 71 to 73, respectively.

The input electrodes on the rear surfaces of the semiconductor chips 60b to 60d are bonded to the main current lead frames 52 to 54, respectively. The output electrodes 62 of the semiconductor chips 60b to 60d on the main current lead frames 52 to 54 are connected directly to the main current lead frames 55 to 57 via the main current wires 74 to 76, respectively.

The control ICs 100 and 101 are disposed on a predetermined control lead frame 90 and are electrically connected to other control lead frames 90. The control IC 100 is an HVIC. The control IC 100 is connected directly to the control electrodes 61 of the high-side semiconductor chips 60a1 to 60a3 with control wires 81 to 83. The control IC 101 is an LVIC. The control IC 101 is connected directly to the control electrodes 61 of the low-side semiconductor chips 60b to 60d with the control wires 84 to 86.

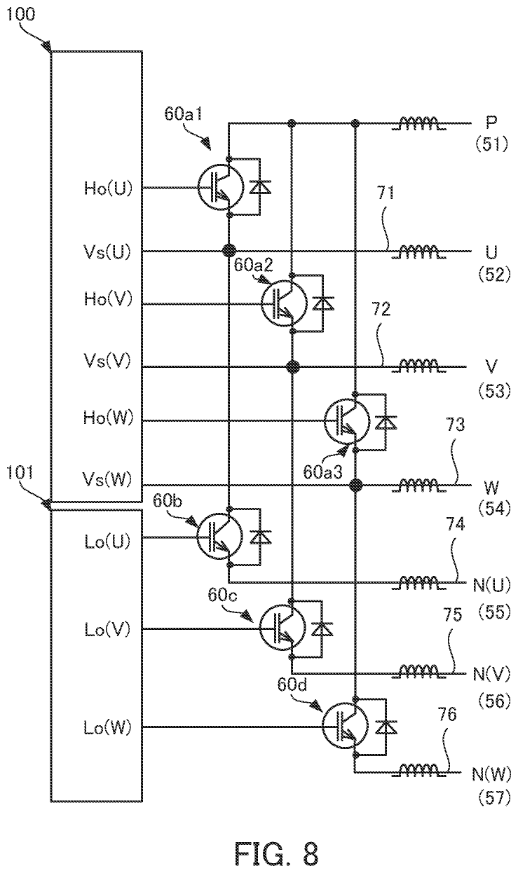

The following describes a circuit configuration that is implemented by the above-described main current lead frames 51 to 57, control lead frames 90, main current wires 71 to 76, semiconductor chips 60a1 to 60a3 and 60b to 60d, and control ICs 100 and 101, with reference to FIG. 8, as well as FIG. 7. FIG. 8 is an equivalent circuit diagram illustrating a circuit that implements functions of the semiconductor device according to the reference example.

The semiconductor device 1000 includes a three-phase inverter circuit, as illustrated in FIG. 8. The positive electrode and negative electrode of an external direct current power connected respectively to a high-potential connecting point P and low-potential connecting points N (U), N (V), and N (W). In addition, a load is connected to connecting points U, V, and W. The semiconductor chips 60a1 to 60a3 and semiconductor chips 60b to 60d convert direct current coming from the connecting point P according to control signals received from the control IC 100 and control IC 101 and output three-phase alternating current from the connecting points U, V, and W.

The connecting point P corresponds to an end portion of the main current lead frame 51, and is connected to the input electrodes of the semiconductor chips 60a1 to 60a3 via the main current lead frame 51. The output electrode 62 of the semiconductor chip 60a1 on the main current lead frame 51 is connected to the input electrode of the semiconductor chip 60b via the main current wire 71 and main current lead frame 52.

The connecting point U corresponds to an end portion of the main current lead frame 52 and is connected to the input electrode of the semiconductor chip 60b via the main current lead frame 52. The connecting point V corresponds to an end potion of the main current lead frame 53, and is connected to the input electrode of the semiconductor chip 60c via the main current lead frame 53 and to the output electrode 62 of the semiconductor chip 60a2 via the main current wire 72.

The connecting point W corresponds to an end portion of the main current lead frame 54, and is connected to the input electrode of the semiconductor chip 60d via the main current lead frame 54 and to the output electrode 62 of the semiconductor chip 60a3 via the main current wires 73.

The connecting point N(U) corresponds to an end portion of the main current lead frame 55 and is connected to the output electrode 62 of the semiconductor chip 60b via the main current wire 74. The connecting point N (V) corresponds to an end portion of the main current lead frame 56 and is connected to the output electrode 62 of the semiconductor chip 60c via the main current wire 75. The connecting point N (W) corresponds to an end portion of the main current lead frame 57 and is connected to the output electrode 62 of the semiconductor chip 60d via the main current wire 76.

This semiconductor device 1000 has the following risk. When the current per unit time during switching rapidly changes, back electromotive force may be applied to the semiconductor chips 60a1 to 60a3 and 60b to 60d due to the wiring inductance of the main current wires 71 to 75 and main current lead frame 51, which may damage the semiconductor chips 60a1 to 60a3 and 60b to 60d.

For example, current and voltage during switching of the semiconductor device 1000 with a rated voltage of 600 V and a rated current of 30 A were measured. The following measurement result was observed. When the semiconductor device 1000 was operated at a driving voltage of 400 V, the voltage value of the semiconductor chip 60a1 in the semiconductor device 1000 exceeded the chip's breakdown voltage of 600 V because of the integration of the back electromotive force produced by the rate of change of current (di/dt) during a turn-off phase and the wiring inductance of the main current lead frame 51 and main current wire 71. In this case, the semiconductor chip 60a1 is damaged, leading to malfunction of the semiconductor device 1000.

By contrast, in the semiconductor device 1, the output electrode 3g of each of the low-side semiconductor chips 3b to 3d is connected to the wiring region 11f of the main current lead frame 11 on the positive electrode side, with the corresponding one of the wiring members 40a to 40c via the insulating spacer 43. That is, snubber capacitors are formed between the input electrodes 3h of the semiconductor chips 3a1 to 3a3 and the output electrodes 3g of the semiconductor chips 3b to 3d. In the semiconductor device 1, the snubber capacitors absorb the back electromotive force produced due to the wiring inductance of the main current lead frame 11 and wiring members 41a to 41c and 40a to 40c. As a result, the back electromotive force to be applied to the semiconductor chips 3a1 to 3a3 and 3b to 3d is reduced, which prevents damage to the semiconductor chips 3a1 to 3a3 and 3b to 3d.

The above-described semiconductor device 1 includes the semiconductor chip 3a1, main current lead frame 11, semiconductor chip 3b, main current lead frame 13, and wiring member 40a. The semiconductor chip 3a1 has the output electrode 3g on the front surface thereof and the input electrode 3h on the rear surface thereof. The main current lead frame 11 includes the chip region 11c to which the input electrode 3h of the semiconductor chip 3a1 is bonded, and the wiring region 11f. The semiconductor chip 3b has the output electrode 3g on the front surface thereof and the input electrode 3h on the rear surface thereof, and is adjacent to the side of the chip region 11c. The main current lead frame 13 is electrically connected to the output electrode 3g of the semiconductor chip 3b. The wiring member 40a is connected to the output electrode 3g of the semiconductor chip 3b and to the wiring region 11f of the main current lead frame 11 via the insulating spacer 43. In this case, a snubber capacitor is formed by the wiring member 40a and spacer 43 between the input electrode 3h of the semiconductor chip 3a1 and the output electrode 3g of the semiconductor chip 3b. The snubber capacitor absorbs back electromotive force produced due to the wiring inductance of the wiring member 40a and main current lead frame 11, which prevents voltage breakdown of the semiconductor chips 3a1 and 3b. Similarly, voltage breakdown is prevented in the semiconductor chips 3a2 and 3c and the semiconductor chips 3a3 and 3d. As a result, a reduction in the reliability of the semiconductor device 1 is prevented.

### Second Embodiment

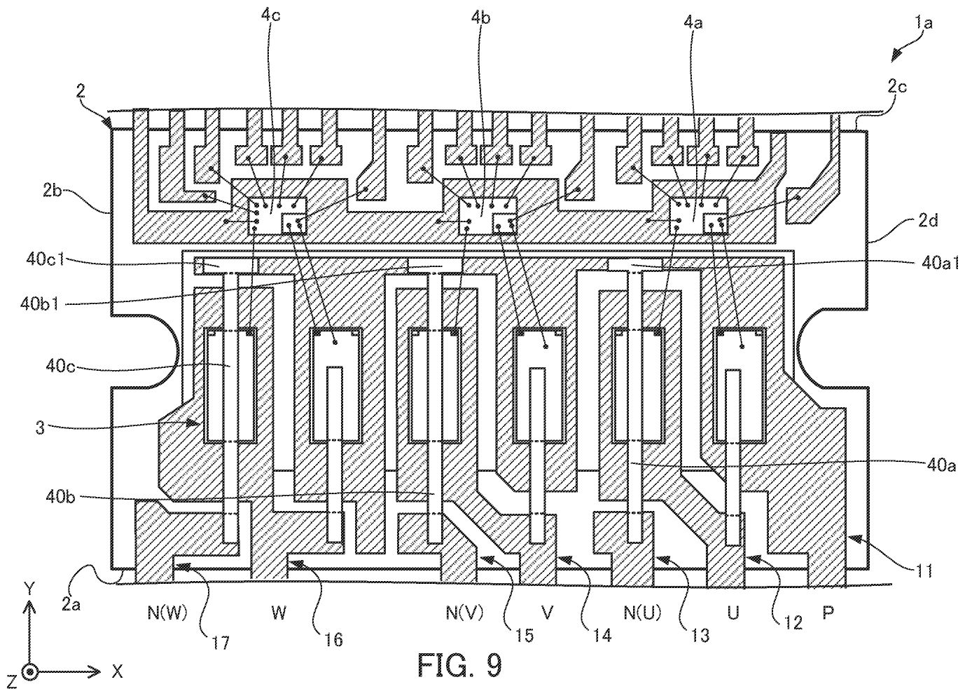

In a second embodiment, a case of changing the capacitance of the snubber capacitors in the semiconductor device 1 will be described, with reference to FIG. 9. FIG. 9 is a plan view of a semiconductor device except for an encapsulating body according to the second embodiment. Note that the same reference numerals as used in the semiconductor device 1 of FIG. 3 are given to the corresponding components of the semiconductor device 1a of FIG. 9. In addition, some reference numerals are omitted in FIG. 9. FIG. 9 illustrates the position of an encapsulating body 2 as well, just for reference. Wiring members 40a to 40c included in the semiconductor device 1a have different shapes from those in the semiconductor device 1. More specifically, in plan view, the wiring members 40a to 40c included in the semiconductor device 1a each have a bonding region 40a1 to 40c1 at an area overlapping the wiring region 11f of a main current lead frame 11.

The bonding regions 40a1 to 40c1 of the wiring members 40a to 40c extend along the wiring region 11f. More specifically, the wiring members 40a to 40c have a T-shape in plan view. In this connection, although this is not illustrated, spacers 43 are also provided along the wiring region 11f so as to correspond to the bonding regions 40a1 to 40c1 of the wiring members 40a to 40c, respectively.

FIG. 9 illustrates the case where the bonding regions 40a1 to 40c1 extend in the +X directions along the wiring region 11f. The bonding regions 40a1 to 40c1 are not limited to this case, but may extend in the +X direction or −X direction along the wiring region 11f. Alternatively, the bonding regions 40a1 to 40c1 may have different shapes. In this connection, the spacers 43 are provided so as to correspond in shape to the bonding regions 40a1 to 40c1 of the wiring members 40a to 40c. Note that the areas of the wiring members 40a to 40c overlapping the wiring region 11f of the main current lead frame 11 in the semiconductor device 1a are larger than the areas of the wiring members 40a to 40c overlapping the wiring region 11f of the main current lead frame 11 in the semiconductor device 1. Therefore, the capacitance of the snubber capacitors formed in the semiconductor device 1a is greater than that of the snubber capacitors formed in the semiconductor device 1. Thus, the semiconductor device 1a of the second embodiment improves the effect of reducing the back electromotive force, compared with the semiconductor device 1 of the first embodiment.

The way to change the capacitance of the snubber capacitors formed in the semiconductor device 1 is not limited to the one of the second embodiment where the areas of the wiring members 40a to 40c overlapping the wiring region 11f of the main current lead frame 11 are changed. For example, the portions of the wiring members 40a to 40c that overlap the wiring region 11f of the main current lead frame 11 in the semiconductor device 1 may be located closer to the wiring region 11f (may be located farther from the wiring region 11f in some cases). Alternatively, the spacers 43 may be made of a material with high permittivity. Yet alternatively, the above three ways may be combined where appropriate.

### Third Embodiment

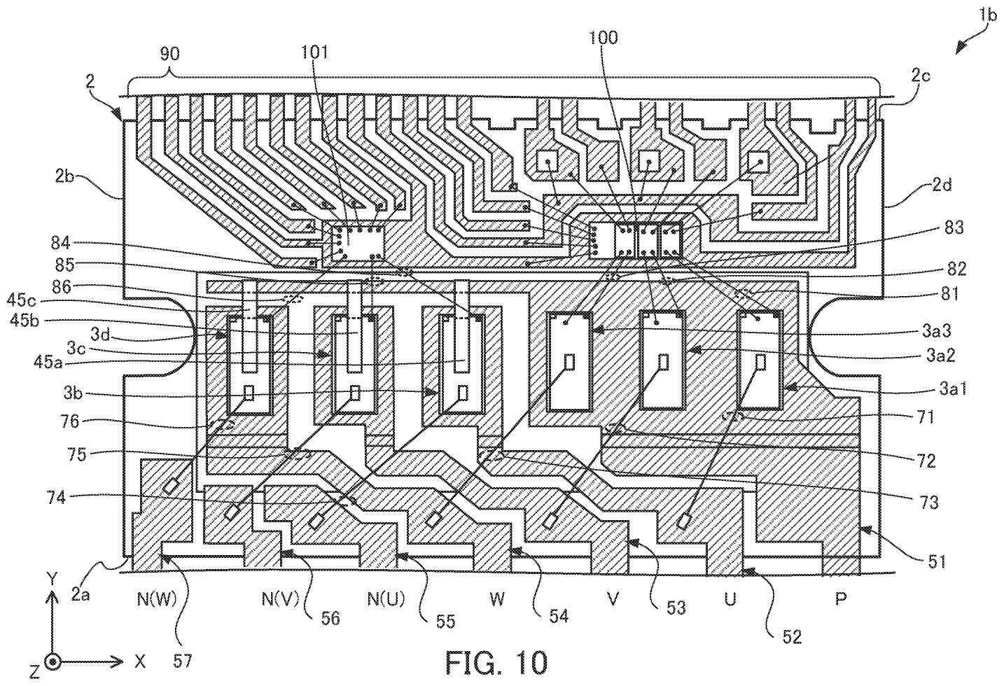

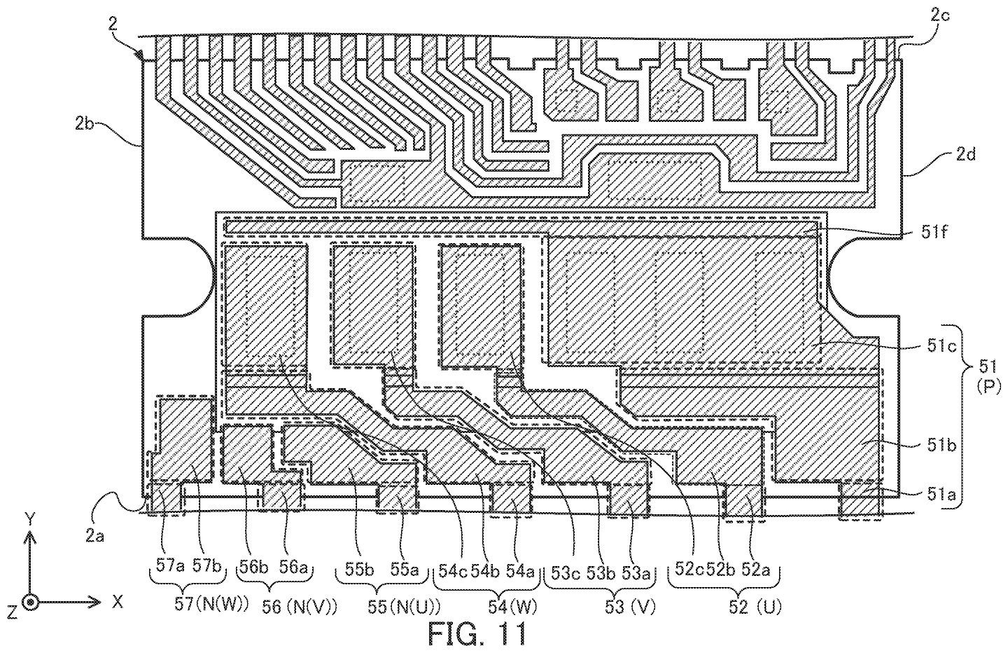

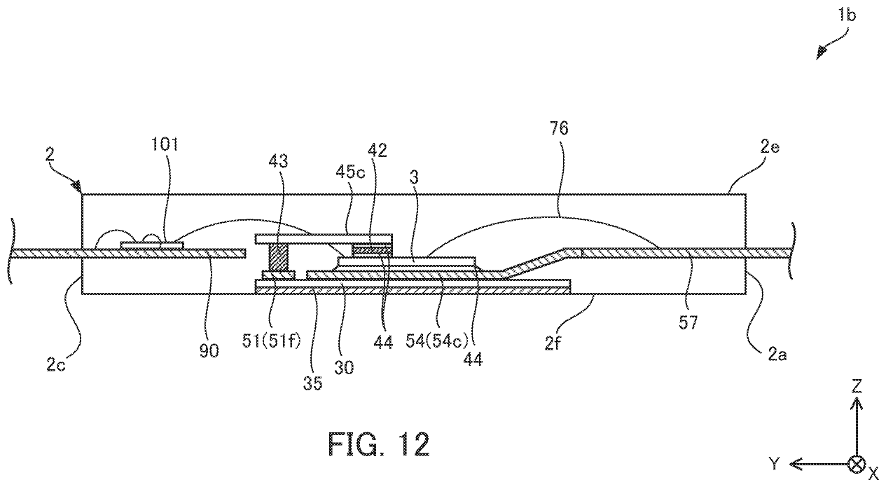

In a third embodiment, a case will be described in which snubber capacitors are formed in the lead frames of the above-described reference example, as in the first embodiment. The following describes a semiconductor device 1b of the third embodiment with reference to FIGS. 10 to 12. FIG. 10 is a plan view of the semiconductor device except for an encapsulating body according to the third embodiment. FIG. 11 is a plan view of lead frames included in the semiconductor device according to the third embodiment. FIG. 12 is a side view of the semiconductor device except for the encapsulating body according to the third embodiment. In this connection, FIGS. 10 and 11 correspond to FIGS. 3 and 4 of the first embodiment. In addition, FIG. 12 corresponds to FIG. 5 of the first embodiment, and is a side view of a −X-side end portion seen in FIG. 10. That is, FIG. 12 is a side view seen in the +X direction from the side where the short side surface 2b is located in FIG. 10. In addition, FIGS. 10 to 12 illustrate the outline of an encapsulating body 2 as well, just for reference.

The semiconductor device 1b includes main current lead frames 51 to 57, a plurality of control lead frames 90, an insulating sheet 30, a heat dissipation plate 35, semiconductor chips 3a1 to 3a3 and 3b to 3d, and control ICs 100 and 101. The semiconductor device 1b also includes wiring members 45a to 45c. The control ICs 100 and 101 are connected directly to the semiconductor chips 3a1 to 3a3 and semiconductor chips 3b to 3d with control wires 81 to 83 and control wires 84 to 86, respectively. The main current lead frames 51 to 57 extend outward (in the −Y direction) from a long side surface 2a of the encapsulating body 2. The plurality of control lead frames 90 extend outward (in the +Y direction) surface 2c of the from a long side encapsulating body 2. In FIGS. 10 to 12, the portions of the main current lead frames 51 to 57 extending from the long side surface 2a and the portions of the plurality of control lead frames 90 extending from the long side surface 2c are not illustrated.

The main current lead frames 51 to 57 are made of the same material as the main current lead frames 11 to 17 of the first embodiment. In addition, the main current lead frames 51 to 57 are spaced by a gap of a predetermined distance or more from one another. This keeps the creepage distances between the main current lead frames 51 to 57.

The main current lead frame 51 integrally includes an external bonding region 51a, a wiring region 51b, a chip region 51c, and a wiring region 51f, as illustrated in FIG. 11. In this connection, the semiconductor chips 3a1 to 3a3 are bonded to the chip region 51c via a bonding member 44.

The external bonding region 51a extends outward (in the −Y direction) from a portion of the long side surface 2a of the encapsulating body 2 adjacent to a short side surface 2d of the encapsulating body 2 in plan view. The external bonding region 51a may be bent at any point so as to extend in the +Z direction.

The wiring region 51b integrally connects to the external bonding region 51a and the chip region 51c. The wiring region 51b extends from the external bonding region 51a to the chip region 51c in the direction toward the long side surface 2c.

The chip region 51c has an area large enough to arrange three semiconductor chips 3a1 to 3a3 therein. In this connection, dotted rectangles depicted in the chip region 51c indicate the positions of the semiconductor chips 3a1 to 3a3. The semiconductor chips 3a1 to 3a3 are bonded to the chip region 51c via the bonding member 44. The semiconductor chips 3a1 to 3a3 are arranged in the direction from the short side surface 2d toward a short side surface 2b of the encapsulating body 2. The wiring region 51f extends from a side of the chip region 51c closest to the long side surface 2c toward the short side surface 2b in parallel to the long side surfaces 2a and 2c. The wiring region 51f extends up to a chip region 54c located closest to the short side surface 2b.

The main current lead frame 52 integrally includes an external bonding region 52a, a wiring region 52b, and a chip region 52c, as illustrated in FIG. 11. A dotted rectangle depicted in the chip region 52c indicates the position of the semiconductor chip 3b. The semiconductor chip 3b is bonded to the chip region 52c via the bonding member 44.

The external bonding region 52a is located next to and on the −X side of the external bonding region 51a and extends outward (in the −Y direction) from the long side surface 2a of the encapsulating body 2 in plan view. The external bonding region 52a may be bent at any point so as to extend in the +Z direction.

The wiring region 52b integrally connects to the external bonding region 52a and the chip region 52c. The wiring region 52b extends from the external bonding region 52a to the chip region 52c between the main current lead frames 51 and 53. The chip region 52c is located between the chip regions 51c and 53c with predetermined gaps from the chip regions 51c and 53c and wiring region 51f.

The main current lead frame 53 integrally includes an external bonding region 53a, a wiring region 53b, and a chip region 53c, as illustrated in FIG. 11. In this connection, a dotted rectangle depicted in the chip region 53c indicates the position of the semiconductor chip 3c. The semiconductor chip 3c is bonded to the chip region 53c via the bonding member 44.

The external bonding region 53a is located next to and on the −X side of the external bonding region 52a and extends outward (in the −Y direction) from the long side surface 2a of the encapsulating body 2 in plan view. The external bonding region 53a may be bent at any point so as to extend in the +Z direction.

The wiring region 53b integrally connects to the external bonding region 53a and the chip region 53c. The wiring region 53b extends from the external bonding region 53a to the chip region 53c between the main current lead frames 52 and 54. The chip region 53c is located between the chip regions 52c and 54c with predetermined gaps from the chip regions 52c and 54c and wiring region 51f.

The main current lead frame 54 integrally

includes an external bonding region 54a, a wiring region 54b, and the chip region 54c, as illustrated in FIG. 11. In this connection, a dotted rectangle depicted in the region chip 54c indicates the position of the semiconductor chip 3d. The semiconductor chip 3d is bonded to the chip region 54c via the bonding member 44.

The external bonding region 54a is located next to and on the −X side of the external bonding region 53a and extends outward (in the −Y direction) from the long side surface 2a of the encapsulating body 2 in plan view. The external bonding region 54a may be bent at any point so as to extend in the +Z direction.

The wiring region 54b integrally connects to the external bonding region 54a and the chip region 54c. The wiring region 54b extends from the external bonding region 54a to the chip region 54c between the main current lead frames 53 and 55. The chip region 54c is located next to the chip region 53c with predetermined gaps from the chip region 53c and wiring region 51f.

The main current lead frame 55 integrally includes an external bonding region 55a and a wiring region 55b, as illustrated in FIG. 11. The external bonding region 55a is located next to and on the −X side of the external bonding region 54a and extends outward (in the −Y direction) from the long side surface 2a of the encapsulating body 2 in plan view. The external bonding region 55a may be bent at any point so as to extend in the +Z direction. The wiring region 55b is integrally connected to the external bonding region 55a. The wiring region 55b extends up to close to a portion of the wiring region 54b adjacent to the chip region 54c with a predetermined gap from the wiring region 54b.

The main current lead frame 56 integrally includes an external bonding region 56a and a wiring region 56b, as illustrated in FIG. 11. The external bonding region 56a is located next to and on the −X side of the external bonding region 55a and extends outward (in the −Y direction) from the long side surface 2a of the encapsulating body 2 in plan view. The external bonding region 56a may be bent at any point so as to extend in the +Z direction. The wiring region 56b is integrally connected to the external bonding region 56a. The wiring region 56b extends up to close to the portion of the wiring region 54b adjacent to the chip region 54c with a predetermined gap from the wiring region 54b.

The main current lead frame 57 integrally includes an external bonding region 57a and a wiring region 57b, as illustrated in FIG. 11. The external bonding region 57a is located next to and on the −X side of the external bonding region 56a and extends outward (in the −Y direction) from the long side surface 2a of the encapsulating body 2 in plan view. The external bonding region 57a may be bent at any point so as to extend in the +Z direction. The wiring region 57b is integrally connected to the external bonding region 57a. The wiring region 57b extends up to close to the portion of the wiring region 54b adjacent to the chip region 54c with a predetermined gap from the wiring region 54b.

In this connection, the external bonding regions 51a to 54a of the main current lead frames 51 to 54 and the main current lead frames 55 to 57 are located vertically above (in the +Z direction) the chip regions 51c to 54c and wiring region 51f. The wiring regions 51b to 54b are inclined to connect the external bonding regions 51a to 54a to the chip regions 51c to 54c, respectively.

The insulating sheet 30, heat dissipation plate 35, semiconductor chips 3a1 to 3a3 and 3b to 3d are made of the same materials as and have the same shapes and the same structures as those in the first embodiment. The control lead frames 90 are made of the same material as and have the same thickness as the control lead frames 20a to 20p and 21 of the first embodiment.

The semiconductor chips 3a1 to 3a3 are arranged in the chip region 51c of the main current lead frame 51 such that their control electrodes 3f face toward the long side surface 2c. The output electrodes 3g of the semiconductor chips 3a1 to 3a3 are connected directly to the wiring regions 52b to 54b of the main current lead frames 52 to 54 with main current wires 71 to 73, respectively.

The semiconductor chips 3b to 3d are arranged in the chip regions 52c to 54c of the main current lead frames 52 to 54, respectively, such that their control electrodes 3f face toward the long side surface 2c. The output electrodes 3g of the semiconductor chips 3b to 3d are connected directly to the wiring regions 55b to 57b of the main current lead frames 55 to 57 with main current wires 74 to 76, respectively.

In addition, the wiring members 45a to 45c are connected to the output electrodes 3g of the semiconductor chips 3b to 3d, respectively, and to the wiring region 51f of the main current lead frame 51. One end portion of each of the wiring members 45a to 45c closest to the long side surface 2a is bonded to the output electrode 3g of the corresponding one of the semiconductor chips 3b to 3d via the bonding member 44, spacer 42, and bonding member 44. The other end portion of each of the wiring members 45a to 45c closest to the long side surface 2c is bonded to the wiring region 51f of the main current lead frame 51 via an insulating spacer 43. The wiring members 45a to 45c are different in length from the wiring members 40a to 40c of the first embodiment, but are made of the same material as and have the same thickness and the same shapes as the wiring members 40a to 40c of the first embodiment.

The plurality of control lead frames 90 are provided on a side of the main current lead frame 51 where the long side surface 2c is located in plan view, as illustrated in FIGS. 10 and 11. As described earlier, the control ICS 100 and 101 are disposed on a predetermined control lead frame 90 and are electrically connected to other control lead frames 90. The control IC 100 is connected directly to the control electrodes 3f of the high-side semiconductor chips 3a1 to 3a3 with the control wires 81 to 83. In addition, the control IC 100 is connected directly connected to the output electrodes 3g of the high-side semiconductor chips 3a1 to 3a3 with sense wires, although the reference numerals are omitted. The control IC 101 is connected directly to the control electrodes 3f of the low-side semiconductor chips 3b to 3d with the control wires 84 to 86.

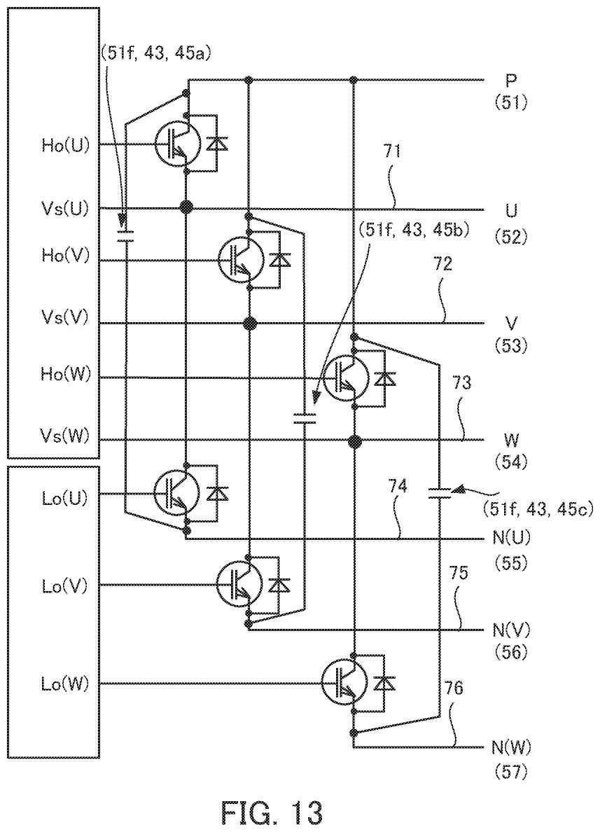

The following describes a circuit configuration that is implemented by the above-described main current lead frames 51 to 57, plurality of control lead frames 90, wiring members 45a to 45c, semiconductor chips 3a1 to 3a3 and 3b to 3d, and control ICs 100 and 101, with reference to FIG. 13, as well as FIGS. 10 to 12. FIG. 13 is an equivalent circuit diagram illustrating a circuit that implements functions of the semiconductor device according to the third embodiment. The circuit configuration formed in the semiconductor device 1b includes snubber capacitors in addition to the circuit configuration of the semiconductor device 1000 of the reference example.

The semiconductor device 1b includes a three-phase inverter circuit, as illustrated in FIG. 13. The positive electrode and negative electrode of an external direct current power supply are connected to a high-potential connecting point P and low-potential connecting points N (U), N (V), and N (W). In addition, a load is connected to connecting points U, V, and W. The semiconductor chips 3a1 to 3a3 and semiconductor chips 3b to 3d convert direct current coming from the connecting point P according to control signals received from the control ICs 100 and 101 and output three-phase alternating current from the connecting points U, V, and W.

The connecting point P corresponds to the external bonding region 51a of the main current lead frame 51 and is connected to the input electrodes 3h of the semiconductor chips 3a1 to 3a3 via the main current lead frame 51. The output electrodes 3g of the semiconductor chips 3a1 to 3a3 on the main current lead frame 51 are connected to the input electrodes 3h of the semiconductor chips 3b to 3d via the main current wires 71 to 73 and main current lead frames 52 to 54, respectively.

The connecting point U corresponds to the external bonding region 52a of the main current lead frame 52, and is connected to the input electrode 3h of the semiconductor chip 3b via the main current lead frame 52 and to the output electrode 3g of the semiconductor chip 3a1 via the main current wire 71.

The connecting point N (U) corresponds to the external bonding region 55a of the main current lead frame 55 and is connected to the output electrode 3g of the semiconductor chip 3b via the main current lead frame 55 and the main current wire 74.

In addition, a snubber capacitor is formed by the wiring region 51f, spacer 43, and wiring member 45a between the output electrode 3g of the semiconductor chip 3b and the input electrode 3h of the semiconductor chip 3a1.

The control IC 100 is connected to the plurality of control lead frames 90 with wires. The control IC 100 inputs a control signal to the control electrodes 3f of the high-side semiconductor chips 3a1 to 3a3 according to signals received from the plurality of control lead frames 90.

The connecting point V corresponds to the external bonding region 53a of the main current lead frame 53, and is connected to the input electrode 3h of the semiconductor chip 3c via the main current lead frame 53 and to the output electrode 3g of the semiconductor chip 3a2 via the main current wire 72. The connecting point N (V) corresponds to the external bonding region 56a of the main current lead frame 56 and is connected to the output electrode 3g of the semiconductor chip 3c via the main current wire 75.

In addition, a snubber capacitor is formed by the wiring region 51f, spacer 43, and wiring member 45b between the output electrode 3g of the semiconductor chip 3c and the input electrode 3h of the semiconductor chip 3a2.

The connecting point W corresponds to the external bonding region 54a of the main current lead frame 54, and is connected to the input electrode 3h of the semiconductor chip 3d via the main current lead frame 54 and to the output electrode 3g of the semiconductor chip 3a3 via the main current wire 73. The connecting point N (W) corresponds to the external bonding region 57a of the main current lead frame 57 and is connected to the output electrode 3g of the semiconductor chip 3d via the main current wire 76.

In addition, a snubber capacitor is formed by the wiring region 51f, spacer 43, and wiring member 45c between the output electrode 3g of the semiconductor chip 3d and the input electrode 3h of the semiconductor chip 3a3.

In addition, the control IC 101 is connected to the plurality of control lead frames 90 with wires. The control IC 101 inputs a control signal to the control electrodes 3f of the low-side semiconductor chips 3b to 3d according to signals received from the plurality of control lead frames 90.

As described above, even in the semiconductor device 1b, the output electrode 3g of each of the low-side semiconductor chips 3b to 3d is connected to the wiring region 11f of the main current lead frame 51 on the positive electrode side, with the corresponding one of the wiring members 45a to 45c via the insulating spacer 43. The is, snubber capacitors are formed between the input electrodes 3h of the semiconductor chips 3a1 to 3a3 and the output electrodes 3g of the semiconductor chips 3b to 3d, respectively. Therefore, in the semiconductor device 1b, back electromotive force produced due to the wiring inductance of the main current lead frame 51 and main current wires 71 to 76 is absorbed by the snubber capacitors. Since the wiring inductance increases, as compared to the first embodiment, the snubber capacitors need to have a large capacitance. However, the wiring inductance decreases, as compared with the reference example, and voltage breakdown of the semiconductor chips 3a1 to 3a3 and 3b to 3d is prevented. As a result, a reduction in the reliability of the semiconductor device 1b is prevented.

The disclosed techniques make it possible to reduce the generation of wiring inductance and to prevent a reduction in the reliability of a semiconductor device.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a first semiconductor chip having a first output electrode on a front surface thereof and a first input electrode on a rear surface thereof;
a first lead frame including a first chip region to which the first input electrode of the first semiconductor chip is bonded, and a first wiring region;
a second semiconductor chip having a second output electrode on a front surface thereof and a second input electrode on a rear surface thereof, the second semiconductor chip being adjacent to the first chip region;
an other lead frame electrically connected to the second output electrode of the second semiconductor chip; and
a wiring member connected to the second output electrode of the second semiconductor chip and to the first wiring region of the first lead frame via an insulating member.

2. The semiconductor device according to claim 1, further comprising:
a second lead frame,
wherein the second lead frame includes a second chip region adjacent to the first chip region, and a second wiring region to which the first output electrode of the first semiconductor chip is electrically connected, the second input electrode of the second semiconductor chip being bonded to the second chip region.

3. The semiconductor device according to claim 2, wherein
the second chip region of the second lead frame is adjacent to and faces the first chip region in a first direction, and
the first wiring region of the first lead frame extends in the first direction at a first side of the second chip region of the second lead frame.

4. The semiconductor device according to claim 3, wherein the other lead frame is located at a second side of the second chip region of the second lead frame opposite to the first side in a second direction orthogonal to the first direction.

5. The semiconductor device according to claim 4, wherein the second wiring region of the second lead frame extends from the second chip region toward a third side of the first chip region, the third side and the second side facing in the second direction.

6. The semiconductor device according to claim 5, wherein the wiring member has a flat plate shape and is rectangular in a plan view of the semiconductor device.

7. The semiconductor device according to claim 6, wherein the wiring member further extends beyond the second output electrode of the second semiconductor chip toward the second side of the second chip region and is connected to the other lead frame.

8. The semiconductor device according to claim 7, wherein
the first semiconductor chip, the first chip region, the second lead frame, the second semiconductor chip, and the wiring member are each provided in plurality,
the plurality of first semiconductor chips are respectively bonded to respective ones of the plurality of first chip regions,
the plurality of second lead frames being arranged in a line in the first direction,
the plurality of second semiconductor chips are respectively bonded to respective ones of the plurality of second lead frames,
the first wiring region of the first lead frame extends in the first direction so as to be provided at the first sides of the second chip regions of the plurality of second lead frames,
the other lead frame is provided in plurality as a plurality of third lead frames that are respectively and electrically connected to respective ones of the second output electrodes of the plurality of second semiconductor chips, and
the plurality of wiring members are respectively connected to respective ones of the second output electrodes of the plurality of second semiconductor chips and are each connected to the first wiring region of the first lead frame via the insulating member.

9. The semiconductor device according to claim 8, wherein
the plurality of first chip regions of the first lead frame are aligned in the first direction in the first wiring region with a predetermined gap from one another and each are connected to the first wiring region, and
the second chip regions of the plurality of second lead frames are arranged, adjacent to the plurality of first chip regions, along the first wiring region.

10. The semiconductor device according to claim 9, wherein
each of the plurality of first semiconductor chips has a first control electrode in an end portion of the front surface thereof,
each of the plurality of second semiconductor chips has a second control electrode in an end portion of the front surface thereof,
the plurality of f first semiconductor chips are respectively bonded to respective ones of the first chip regions such that the first control electrodes of the plurality of first semiconductor chips respectively face respective ones of fourth sides of the first chip regions of the first lead frames opposite to the third side in the second direction, and
the plurality of second semiconductor chips are respectively bonded to respective ones of the second chip regions of the plurality of second lead frames such that the second control electrodes of the plurality of second semiconductor chips respectively face respective ones of the first sides of the second chip regions of the second lead frames.

11. The semiconductor device according to claim 10, further comprising a control unit that inputs control signals to the first control electrodes and the second control electrodes.

12. The semiconductor device according to claim 11, wherein the control unit is provided at a side of the first wiring region of the first lead frame opposite to a side of the first wiring region where the plurality of second semiconductor chips are disposed in the plan view.

13. The semiconductor device according to claim 12, wherein
the control signals include a first control signal and a second control signal, and
the control unit includes a plurality of control chips that respectively input the first control signal to the first control electrode and the second control signal to the second control electrode.

14. The semiconductor device according to claim 1, wherein a portion of the wiring member overlapping the first wiring region of the first lead frame extends along the first wiring region in a plan view of the semiconductor device.

15. The semiconductor device according to claim 1, wherein the wiring member is connected to the second output electrode via a conductive spacer.

16. The semiconductor device according to claim 1, wherein the wiring member has a portion projecting toward the second output electrode so that the wiring member is connected at the projecting portion to the second output electrode.

17. The semiconductor device according to claim 1, wherein the insulating member is a dielectric.

18. The semiconductor device according to claim 1, wherein the insulating member is a chip capacitor.
